(19) United States
(12) Patent Application Publication
(10) Pub. No.: US 2025/0123161 A1
(43) Pub. Date: Apr. 17, 2025

(54) SENSOR ASSEMBLY HAVING FORCE AND TEMPERATURE SENSING CAPABILITIES

(71) Applicant: The Hong Kong University of Science and Technology, Hong Kong (CN)

(72) Inventors: Yajing SHEN, Hong Kong (CN); Xiong YANG, Hong Kong (CN)

(21) Appl. No.: 18/823,064

(22) Filed: Sep. 3, 2024

Related U.S. Application Data
(60) Provisional application No. 63/589,989, filed on Oct. 12, 2023.

(51) Int. Cl. G01L 1/14; G01K 7/16; G01R 33/07; H05K 1/18

(52) U.S. Cl. CPC G01L 1/146; G01K 7/16; G01R 33/07; H05K 1/18; H05K 2201/083; H05K 2201/10015; H05K 2201/10151

(57) ABSTRACT

A sensor assembly includes a temperature sensing layer, a tangential force sensing layer, and a floating-mountain multi-layer capacitor, where the temperature sensing layer is configured to detect temperature of an object contacting the sensor assembly, the tangential force sensing layer is configured to detect a tangential force applied by the object to the sensor assembly, and the floating-mountain multi-layer capacitor is configured to detect a normal force applied by the object to the sensor assembly.

### CROSS-REFERENCE TO RELATED APPLICATIONS

This patent application claims the benefit of U.S. Provisional Patent Application No. 63/589,989, filed Oct. 12, 2023, which is incorporated by reference herein in its entirety.

### TECHNICAL FIELD

This application relates to the technical field of sensors, including, for example, sensors for robots.

### BACKGROUND

For robots, sensors play a crucial role in helping them to understand the world and perform tasks more efficiently. To this end, various soft sensors based on different working principles with force or temperature sensing capabilities have been developed to try to meet the requirements of dexterous object manipulation and safe human-robot cooperation.

For example, piezoresistive and piezoelectric composite material can recognize different surface conditions by detecting pressure and vibration information. Electrical impedance and acoustic tomography may be combined for the measurement of pressure and light touch.

A flexible temperature sensor film based on a composite material of plant pectin and cross-linked ions has a high-sensitivity temperature-sensing performance similar to that of snake's pit membrane in nature.

Traditional force measurement principles, such as piezo and resistance, exhibit good linearity in measurement but lack directional sensitivity and cannot distinguish between different directions of tangential forces. On the other hand, force sensing arrays or optical field measurement principles can achieve omnidirectional force sensing but come with increased structural complexity.

Magnetic field sensors have good directional sensitivity and compact structures that can recognize tangential forces in any direction. However, magnetic field changes are caused by normal pressure, and when both normal and shear forces exist, the sensor cannot achieve numerical decoupling of the two.

Moreover, most of the traditional force and temperature measurement methods can mutually affect each other. How to achieve temperature measurement and decoupling within the range of common scenarios is also a difficulty.

In sum, although there have been advancements in conventional sensors such that conventional sensors can measure various signals, conventional sensors are still subject to limitations in the numerical decoupling of multiple signals due to interference among sensing principles.

### SUMMARY

In an example embodiment, the present disclosure provides a sensor assembly. The sensor assembly includes: a temperature sensing layer configured to detect temperature of an object contacting the sensor assembly; at least one tangential force sensing layer configured to detect a tangential force applied by the object to the sensor assembly; and a floating-mountain multi-layer capacitor configured to detect a normal force applied by the object to the sensor assembly.

In a further embodiment, the temperature sensing layer is disposed above the at least one tangential force sensing layer and the floating mountain multi-layer capacitor, and wherein the temperature sensing layer provides a contact surface for the object or is closer to the contact surface for the object than the at least one tangential force sensing layer and the floating mountain multi-layer capacitor.

In a further embodiment, the temperature sensing layer, the at least one tangential force sensing layer, and the floating-mountain multi-layer capacitor are connected to a controller or a processor.

In a further embodiment, the controller or the processor is configured to independently determine the temperature of the object, the tangential force applied by the object, and the normal force applied by the object based on respective measurements from the temperature sensing layer, the tangential force sensing layer, and the floating-mountain multi-layer capacitor.

In a further embodiment, the temperature sensing layer comprises a thermosensitive ion gel disposed within an encapsulation material.

In a further embodiment, the at least one tangential force sensing layer comprises a Halbach magnetic film and a Hall sensor.

In a further embodiment, the Hall sensor is disposed on a printed circuit board.

In a further embodiment, the floating-mountain multi-layer capacitor is disposed between the Halbach magnetic film and the printed circuit board.

In a further embodiment, the Halbach magnetic film comprises an inner portion having a first magnetization and a coaxial outer portion disposed around the inner portion and having a second magnetization opposite that of the inner portion.

In a further embodiment, detecting the tangential force includes detecting a direction of the tangential force and a magnitude of the tangential force.

In a further embodiment, the floating-mountain multi-layer capacitor comprises two positive electrodes and two negative electrodes.

In a further embodiment, the two positive electrodes and the two negative electrodes are arranged within the floating-mountain multi-layer capacitor such that a first positive electrode is disposed above a first negative electrode, the first negative electrode is disposed above a second positive electrode, and the second positive electrode is disposed above a second negative electrode.

In a further embodiment, the first positive electrode has a smaller width than the first negative electrode, the first negative electrode has a smaller width than the second positive electrode, and the second positive electrode has a smaller width than the second negative electrode.

In a further embodiment, the first positive electrode is configured to move in a direction corresponding to the applied tangential force without interfering with the detection of the applied normal force.

In a further embodiment, the floating-mountain multi-layer capacitor comprises electrodes, and wherein the floating-mountain multi-layer capacitor is configured such that a distance between the electrodes is decreased in a direction corresponding to the applied normal force based on application of the normal force.

In a further embodiment, the floating-mountain multi-layer capacitor comprises electrodes embedded in an elastic material.

In another example embodiment, the present disclosure provides a floating-mountain multi-layer capacitor. The floating-mountain multi-layer capacitor includes: a plurality of electrodes; and an elastic material encapsulating the plurality of electrodes. The plurality of electrodes and the elastic material are configured such that, based on a normal force being applied to the floating-mountain multi-layer capacitor, a distance between electrodes of the plurality of electrodes is decreased in a direction corresponding to the applied normal force.

In a further embodiment, the plurality of electrodes comprise two positive electrodes and the two negative electrodes arranged within the floating-mountain multi-layer capacitor such that a first positive electrode is disposed above a first negative electrode, the first negative electrode is disposed above a second positive electrode, and the second positive electrode is disposed above a second negative electrode.

In a further embodiment, the first positive electrode has a smaller width than the first negative electrode, the first negative electrode has a smaller width than the second positive electrode, and the second positive electrode has a smaller width than the second negative electrode.

In yet another example embodiment, the present disclosure provides an apparatus for sensing tangential force. The apparatus includes: a first layer comprising a Halbach magnetic film; and a second layer comprising a Hall sensor disposed on a printed circuit board. The Hall sensor is configured to detect a voltage corresponding to displacement of the magnetic field based on an applied tangential force.

In a further embodiment, the Halbach magnetic film comprises an inner portion having a first magnetization and a coaxial outer portion disposed around the inner portion and having a second magnetization opposite that of the inner portion.

### BRIEF DESCRIPTION OF THE DRAWINGS

FIG. 1 depicts an exemplary flowchart of a contact object interfacing with a multi-layered sensor assembly according to an exemplary embodiment of the present disclosure;

FIG. 2 depicts a schematic structural diagram of a multi-layered sensor assembly capable of decoupled measurements of normal force, tangential force, and temperature according to an exemplary embodiment of the present disclosure;

FIGS. 3A-3C depict schematic flowcharts of methods of forming respective parts of a sensor assembly according to exemplary embodiments of the present disclosure;

FIG. 4 depicts a plot showing an exemplary simulation of a Halbach magnetic field distribution;

FIG. 5 depicts a schematic diagram showing an example of how a tangential force changes the relationship between an exemplary Halbach magnetic film and a Hall sensor;

FIGS. 6-11 depict plots showing exemplary results of quantitative testing of an exemplary implementation of the present disclosure;

FIGS. 12A-12C depict schematic diagrams showing an example of how tangential and normal forces affect an exemplary floating-mountain multi-layer structure according to an exemplary embodiment of the present disclosure;

FIG. 12D depicts a circuit diagram showing an example of how a conversion circuit connects a capacitor of an exemplary floating-mountain multi-layer structure to an embodiment of the present disclosure; and

FIGS. 13-21 depict plots showing qualities and results of quantitative testing of an exemplary implementation of the present disclosure.

### DETAILED DESCRIPTION

Exemplary embodiments of the present disclosure provide for decoupled, flexible sensor assemblies capable of multi-signal sensing. This may, for example, enable higher levels of autonomous decision-making and task planning for robots.

Additionally, exemplary embodiments of the present disclosure provide for a multi-signal sensor assembly capable of achieving numerical decoupling among various types of signals, which significantly enhance the environmental adaptability of robots.

In an exemplary embodiment, the multi-layered flexible sensing assembly includes three types of receptors for decoupled normal force, full-directional tangential force, and temperature sensing, respectively. It will be appreciated that sensor assemblies according to exemplary embodiments of the present disclosure may be analogous to receptors in human skin which allow humans to sense characteristics of their environment such as pressure, temperature, and pain, thus providing robots with enhanced environmental sensing capabilities.

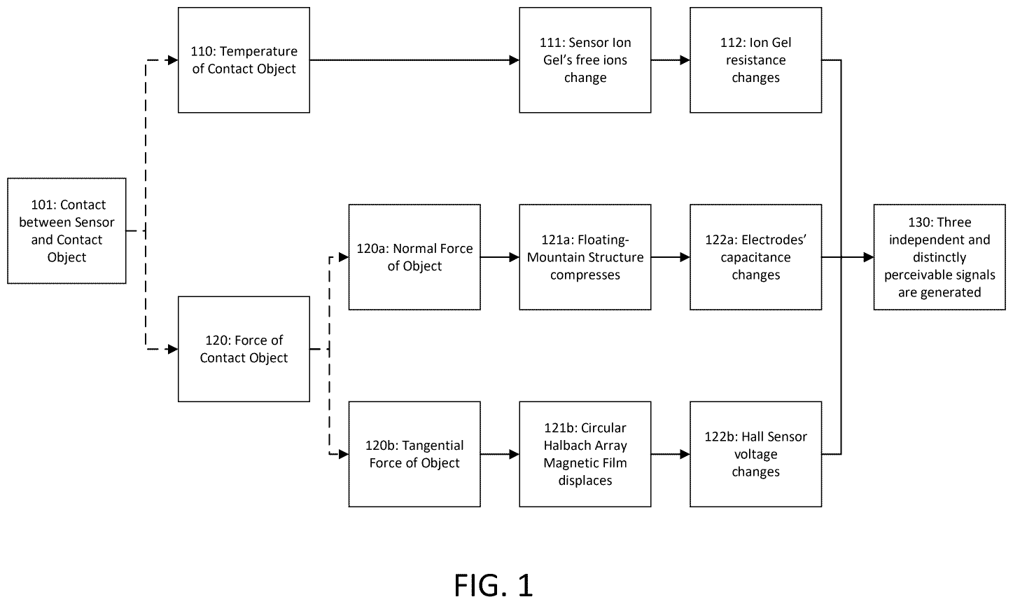

FIG. 1 depicts an exemplary flowchart of a contact object interfacing with a multi-layered sensor assembly according to an exemplary embodiment of the present disclosure.

Stage 101 represents contact occurring between the sensor and a contact object. This contact includes a detectable temperature of the contact object (stage 110), as well as a detectable force of the contact object (stage 120).

As shown at stage 111, the temperature of the contact object affects the temperature of the sensor's ion gel, altering the number of free ions within the gel. This changes the ion gel resistance (stage 112), generating an independent and distinctly perceivable signal.

With regard to force detection (stage 120), the input force component comprises normal force in a normal or vertical direction (stage 120a) and tangential force in a tangential or horizontal direction (120b), wherein both directions are defined with respect to a surface of the sensor. As shown in stage 121a, the normal force acts upon a floating-mountain structure, causing it to compress in the normal direction. Because electrodes are embedded within the floating-mountain structure, this vertical compression alters their capacitance (stage 122a), generating another independent and distinctly perceivable signal. The tangential force displaces a Halbach array magnetic film embedded in the sensor (stage 121b), affecting the voltage of the Hall sensor beneath the film (stage 122b), thereby generating an additional independent and distinctly perceivable signal.

Thus, as shown at stage 130, a sensor assembly according to an exemplary embodiment of the present disclosure is capable of generating three independent and distinctly perceivable signals corresponding to temperature, normal force, and tangential force of a contact object contacting a surface of the sensor assembly.

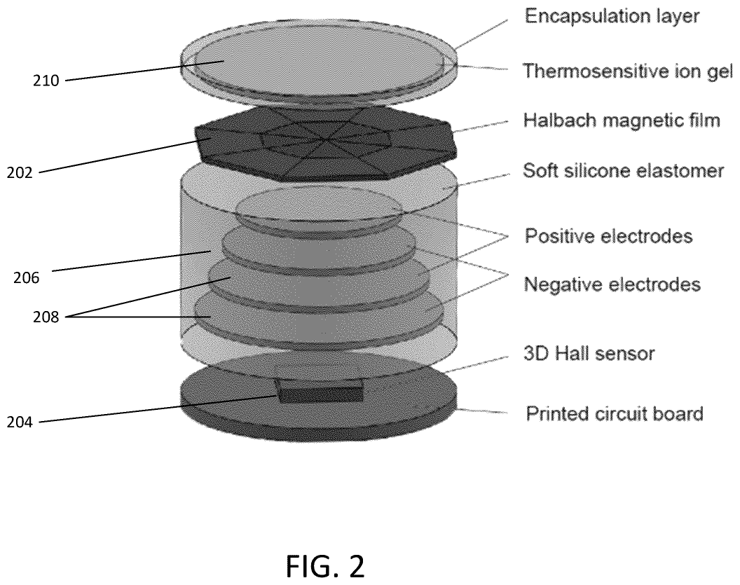

FIG. 2 depicts a schematic structural diagram of a multi-layered sensor assembly capable of decoupled measurements of normal force, tangential force, and temperature according to an exemplary embodiment of the present disclosure. A circular coaxial magnetic film 202 combined with Hall sensors 204 is provided to measure both the direction and magnitude of tangential forces in all directions (providing directional sensitivity with respect to the magnetic fields). Additionally, for normal pressure sensing, a floating-mountain multi-layer structure 206 provides capacitive measurements (with good dynamic response), thereby achieving physical decoupling between normal and tangential forces. The sensor assembly is further configured for temperature measurement based on the temperature-sensitive properties of an ion gel 210, where ion movement remains insensitive to external pressure and deformation, allowing for decoupled temperature and force measurements. Thus, it will be appreciated that the sensor assembly decouples the measurement capabilities for multiple signals, offering the potential for higher-level robot motion control, autonomous decision-making, and task planning.

The measurement of full-directional tangential forces is achieved through a Hall element 204 combined with a Halbach magnetic array 202 designed for single-sided omnidirectional symmetry. The direction of the tangential force is only related to the ratio of the magnetic field strengths in the x-y direction, while the magnitude of the tangential force is positively correlated with the total strength of the radial magnetic field. The measurement of normal pressure is achieved through capacitive measurements, and the vertical sensitivity and horizontal insensitivity of the capacitive measurements are achieved through a floating-mountain multi-layered structure 206. The combination of the Halbach magnetic array 202 and the floating-mountain capacitors 208 retains the directional sensitivity to the magnetic field change and the high dynamic response of the capacitance, achieving a complete decoupling of normal and tangential forces. The temperature measurement utilizes the conductive properties of an ion gel 210. As ion migration is primarily affected by temperature and insensitive to external pressure and structural deformation, it becomes one of the best choices for temperature decoupled measurement. Sensor assemblies according to exemplary embodiments of the present disclosure are thus able to simultaneously achieve full-directional tangential force sensing, decoupled tangential-normal force sensing, and decoupled temperature-force sensing, providing possibilities for higher-level environmental perception, motion control, autonomous decision-making, and task planning for robots.

The multi-layered flexible sensor assembly with three types of receptors is configured to decouple normal force, full-directional tangential force, and temperature sensing. As shown in FIG. 2, the sensor assembly includes three parts, i.e. an ion gel based temperature sensing layer, a capacitor based normal force sensing layer, and a magnetic field based tangential force sensing layer. By microfabrication and molding, all these functions are integrated into a compact cylindrical unit, and in an exemplary implementation, the cylindrical structure may have a radius of 6 mm and a height of 8 mm. Unlike conventional multi-signal sensors that provide only a qualitative signal range or use artificial intelligence to obtain an approximate fitted value, sensor assemblies according to exemplary embodiments of the present disclosure can numerically decouple normal force, tangential force and temperature by the structure design and the corresponding signal analysis. These accurate and decoupled signals can help robots to achieve dexterous manipulation and complex tasks that they could not have achieved before, and without the delay and processing power necessary for mathematical approximations.

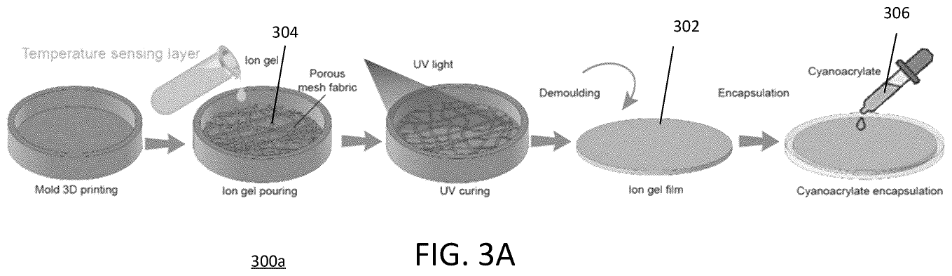

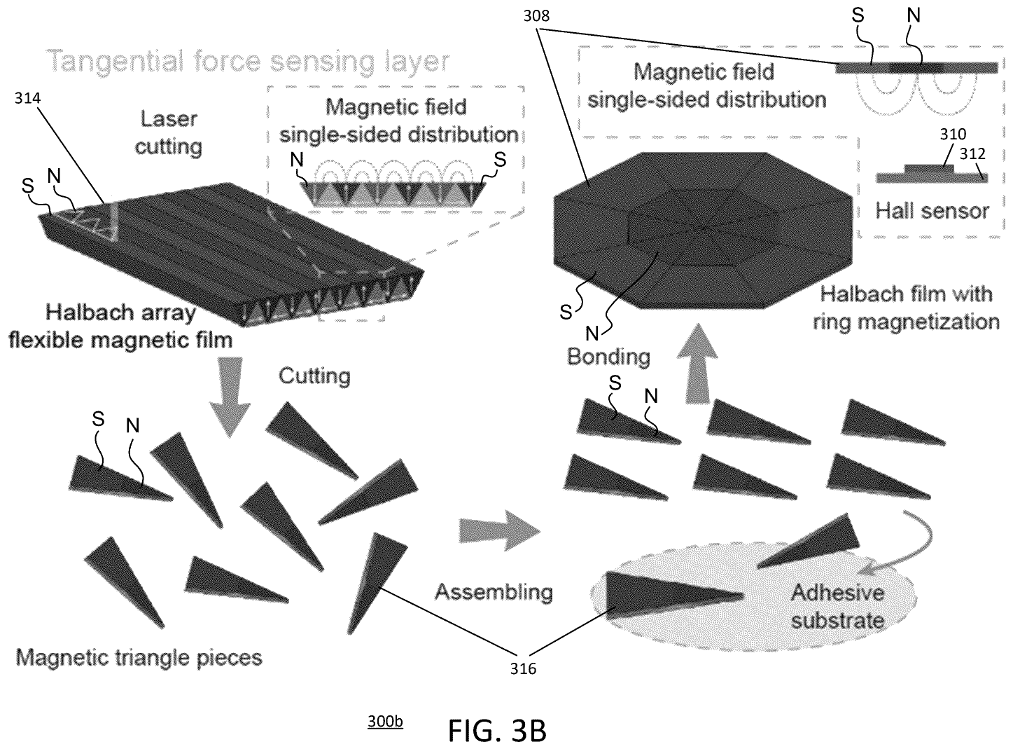

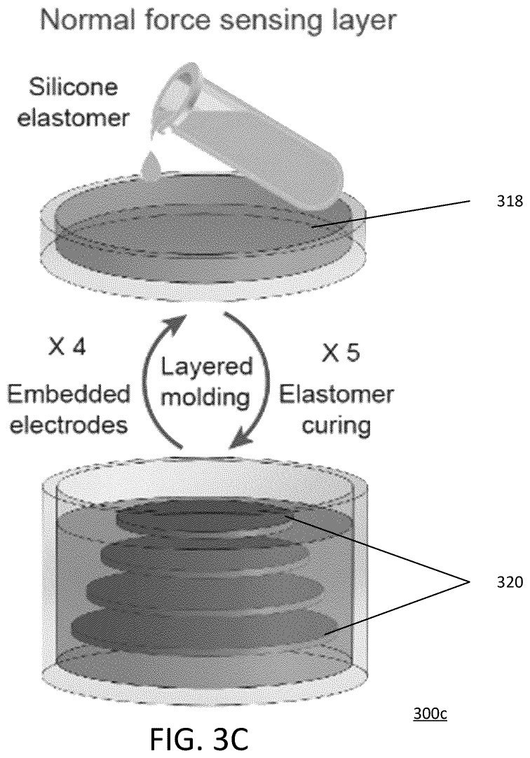

FIGS. 3A-3C depict schematic flowcharts of methods of forming respective parts of a sensor assembly according to exemplary embodiments of the present disclosure.

Referring to FIG. 3A, for each sensor assembly, the temperature layer 300a (e.g., thickness 1 mm) is fabricated with ion gel 302 by molding and followed by curing under UV light. During this, porous mesh fabric 304 is added for mechanical property enhancing (e.g., to maintain stable temperature measurement under stress conditions), and cyanoacrylate 306—or another material suitable for packaging—is adopted for encapsulation to maintain sensing stability. It will be appreciated that other manners of enhancing the mechanical properties may be utilized as well, such as material modification or combination.

The tangential force sensing layer 300b includes the magnetic film 308 (e.g., thickness 0.5 mm) of FIG. 3B disposed under the temperature sensing layer 300a and a Hall sensor 310 (e.g., thickness 0.5 mm) at the bottom printed circuit board (PCB) board 312 (e.g., thickness 1 mm). The fabrication of a circular Halbach pattern magnetic film 308 provides for full-directional tangential force sensing. As shown in FIG. 3B, a rectangular magnetic film with common Halbach array magnetization 314 is first fabricated by a conventional method, e.g. magnetization to the mixture of polydimethylsiloxane (PDMS) and neodymium (NdFeB) magnetic powders, magnetron sputtering, or electrophoretic deposition. Then, a laser may be used to cut the film into small isosceles triangles 316 according to the desired magnetization pattern. Finally, an approximately circular Halbach magnetic film with ring magnetization 308 can be assembled using these isosceles triangles 316.

In this example, a planar Halbach array magnetized film 314 with a north-south magnetic moment of 4 mm can be cut into 8 isosceles triangle modules 316 with a vertex angle of 45 degrees after laser cutting. The 8 isosceles triangle modules can be further arranged to obtain a coaxial Halbach magnetization form 308 that is approximately circular. The inner circle of the assembled nearly circular magnetic film is the south pole, the outer circle is the north pole, and the magnetic field lines are sinusoidally distributed from the center of the circle along the radius to the outside on a single surface. This arrangement allows for the magnetic field based accurate measurement of omnidirectional tangential force.

As shown in FIG. 3B, the planar Halbach array magnetized film 314 has alternating triangular sections of S-pole magnetization and N-pole magnetization, with portions of internal horizontal magnetization disposed between them. The cut triangles each include a first S-pole magnetization portion and a second N-pole magnetization portion, and when assembled into an approximately circular polygonal Halbach film with ring magnetization, the portions of S-pole magnetization form a concentric polygonal ring around the internal portions of N-pole magnetization. This arrangement provides for magnetic field distribution on one side, and the magnetic field lines are sinusoidally distributed from the center of the circle along the radius to the outside, which allows for accurate measurement of omnidirectional tangential force.

The normal force sensing layer 300c (e.g., thickness 5 mm) is between the magnetic film 308 and PCB board 312. To ensure the whole displacement of magnetic film 308 when external tangential force is applied, an elastic material 318 (e.g., silicone elastomer) is used to encapsulate embedded electrodes of the normal force sensing layer 300c. As FIG. 3C shows, four circular electrodes 320 with different sizes are embedded with a gap (e.g., of 1 mm) by repeated molding operations to form the normal force sensing layer.

The signals from the temperature-sensing layer 300a, tangential force sensing layer 300b, and normal force sensing layer 300c are connected to a controller (e.g., a microprogrammed control unit (MCU)) by circuits on the PCB 312. By monitoring the resistance, magnetic field and capacitance change, the temperature, tangential force and normal force information, respectively, can be obtained.

The directional sensitivity of the magnetic field makes it highly suitable for measuring tangential forces in any direction. Unlike other magnetic field-based sensor designs, the magnetic film 308 according to exemplary embodiments of the present disclosure has a circular pattern with a coaxial Halbach array magnetization as shown in FIG. 3B. Magnets and magnet sensors generally have a single pair of poles and are not arranged coaxially.

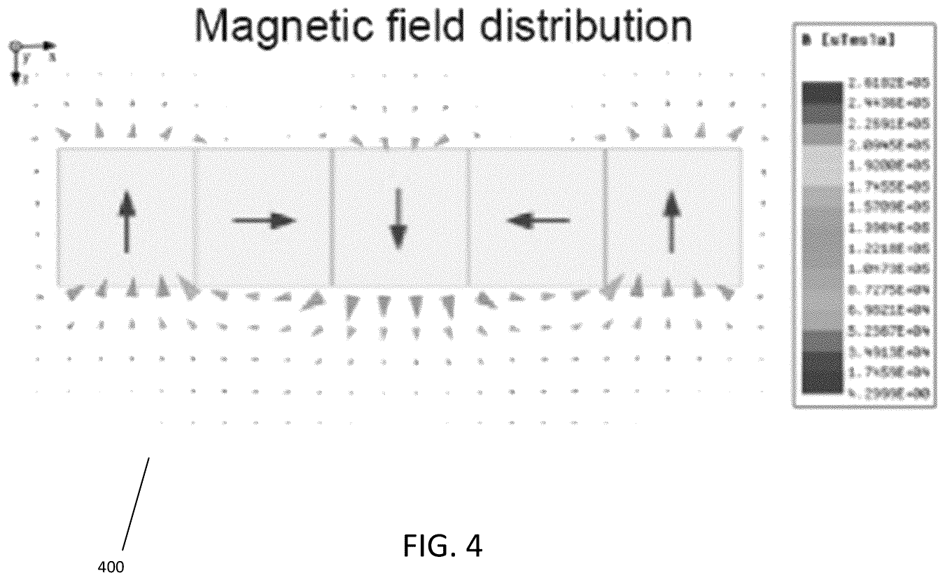

FIG. 4 depicts a plot 400 showing an exemplary simulation of a Halbach magnetic field distribution, which provides a unique magnetization pattern which creates a spatial distribution of the magnetic field that resembles a coaxial sinusoidal pattern on one side. FIG. 4 is a cross-sectional side view of a magnetic film, which shows the difference in magnetic field distribution between the upper and lower surfaces of the magnetic film.

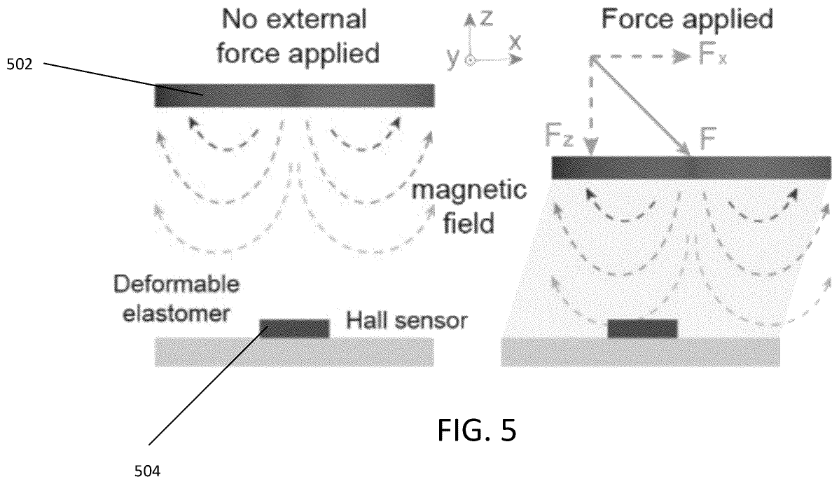

FIG. 5 depicts a schematic diagram showing an example of how a tangential force changes the relationship between an exemplary Halbach magnetic film 502 and a Hall sensor 504 (corresponding to the arrangement shown in FIG. 4). Due to the distinctive magnetization pattern mentioned above, when a tangential external force is acting on the sensor assembly, the direction of the tangential force can be determined by measuring the direction of the magnetic field, while the magnitude of the tangential force is positively correlated with the magnitude of the magnetic field's tangential component in that direction.

Additionally, the one-sided distribution of the magnetic field can mitigate the influence of external magnetic materials on the sensor's measurements, making the measurement results more stable and accurate compared to sensors using conventional magnetic films. As seen in FIG. 4, the magnetic field is weaker on the upper surface of the magnetic film (corresponding to outside of the sensor) and stronger on the lower surface of the magnetic film (corresponding to the inside of the sensor). This means that the sensor is less affected by external magnetic materials while maintaining its own high measurement sensitivity.

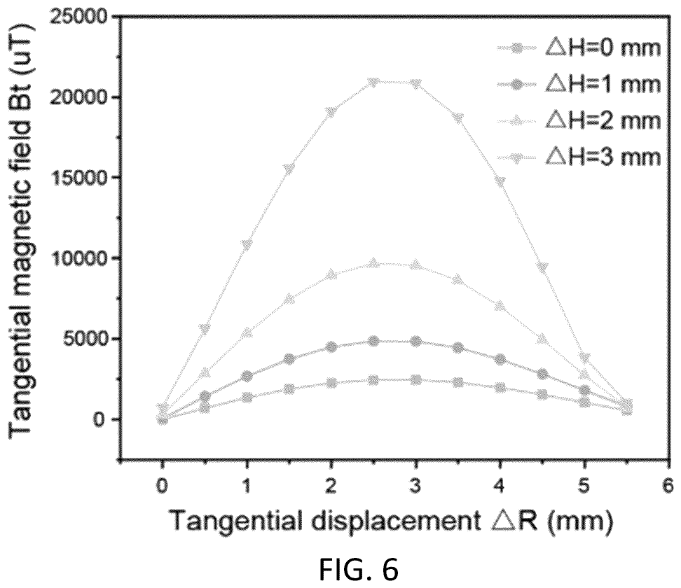

Furthermore, testing was performed to provide a quantitative characterization of the magnetic field distribution and tangential force measurement performance. FIGS. 6-11 depict plots showing exemplary results of such quantitative testing of an exemplary implementation of the present disclosure.

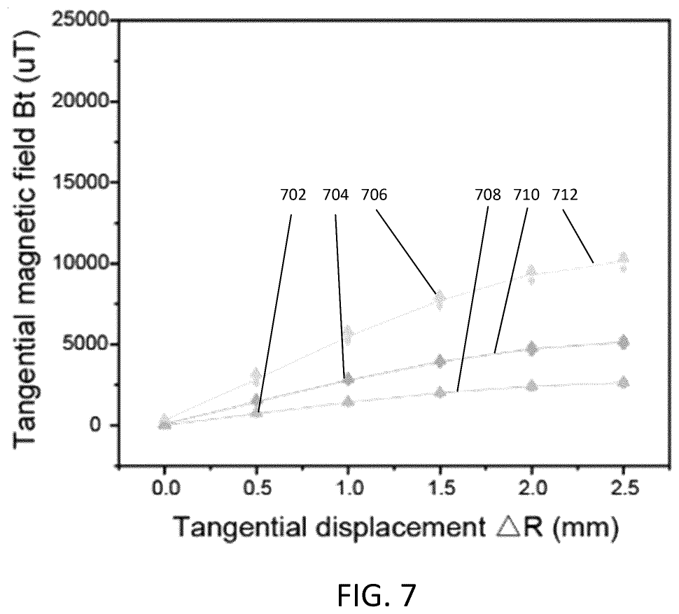

FIG. 6 illustrates the variation in tangential magnetic field strength along the radius of the circular magnetic film. Due to the coaxial circular magnetization distribution, tangential magnetic field strength is the same and varies sinusoidally in all directions at the same height distance. Taking an interval of 0-2.5 mm of tangential displacement within the sensor's working range, it can be observed in FIG. 7, for a given height ΔH, tangential displacement and magnetic field strength have a one-to-one correspondence, meaning that the magnitude of the tangential force corresponds one-to-one with the magnitude of the tangential magnetic field strength. See ground truth values for ΔH=0 mm (702), 1 mm (704), and 2 mm (706) and fitting curve for ΔH=0 mm (708), 1 mm (710), and 2 mm (712). This shows the correspondence between tangential magnetic field strength and tangential force at different heights ΔH.

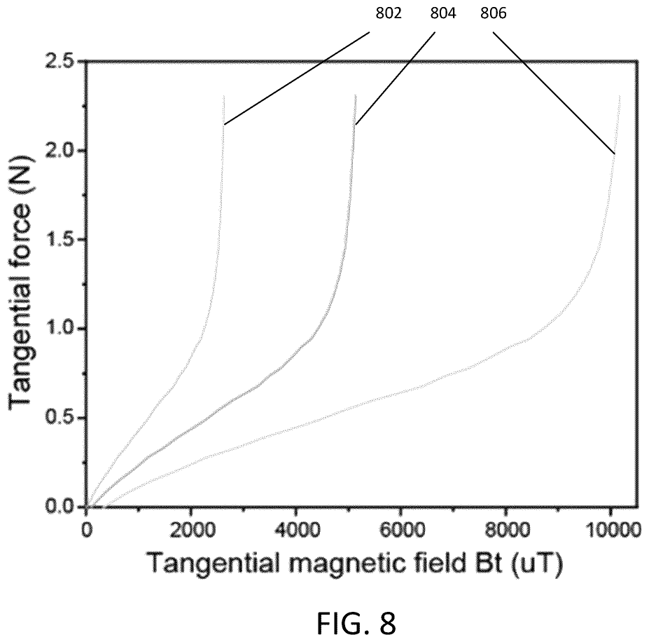

FIG. 8 shows, at a given height ΔH, tangential magnetic field strength initially increases linearly with an increase in tangential force. See values for ΔH=0 mm (802), 1 mm (804), and 2 mm (806). However, as the boundary region (ΔR=2.5 mm) is approached, the increase in the magnetic field slows, indicating reduced sensitivity in measuring tangential forces near the boundary region, in line with the sinusoidal variation pattern of tangential magnetic field strength. The direction of the tangential force is correlated with the direction of the tangential magnetic field.

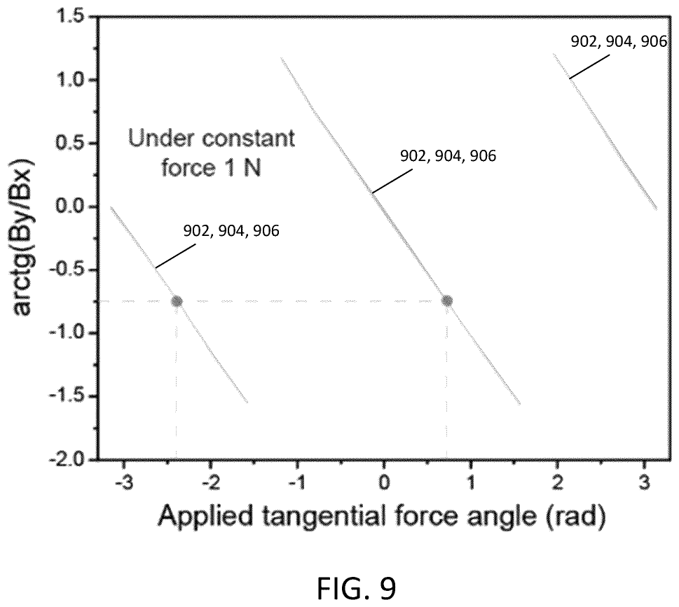

FIG. 9 depicts the manner in which the arctan of the ratio of By and Bx is related to the direction of the tangential force, where By and Bx correspond to the strength of the magnetic field along the y and x directions, respectively. It can be observed that they do not have a one-to-one correspondence due to the presence of both positive and negative values in the magnetic field direction. See values for ΔH=0 mm (902), 1 mm (904), and 2 mm (906), whereby each of the three lines shown in FIG. 9 have three lines superimposed upon each other corresponding to ΔH=0 mm (902), 1 mm (904), and 2 mm (906). Thus, the direction of the tangential force is related to the arctan of the ratio of By and Bx, and is independent of the magnitude of the different normal force.

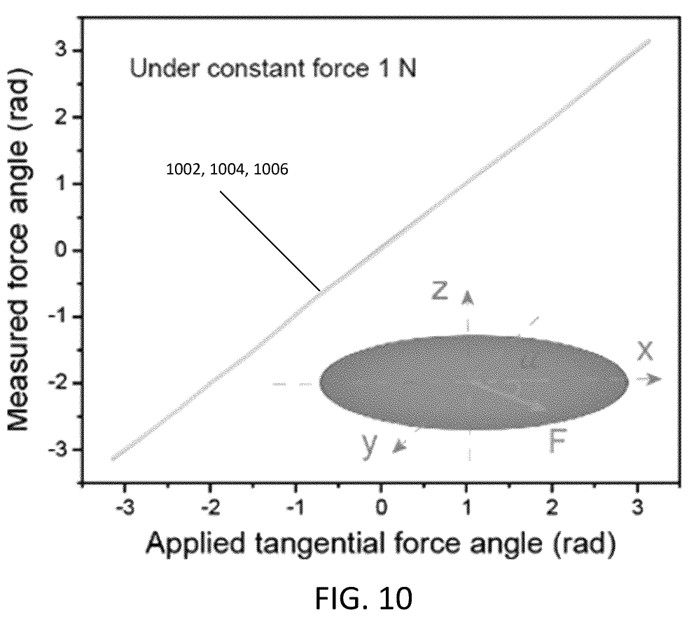

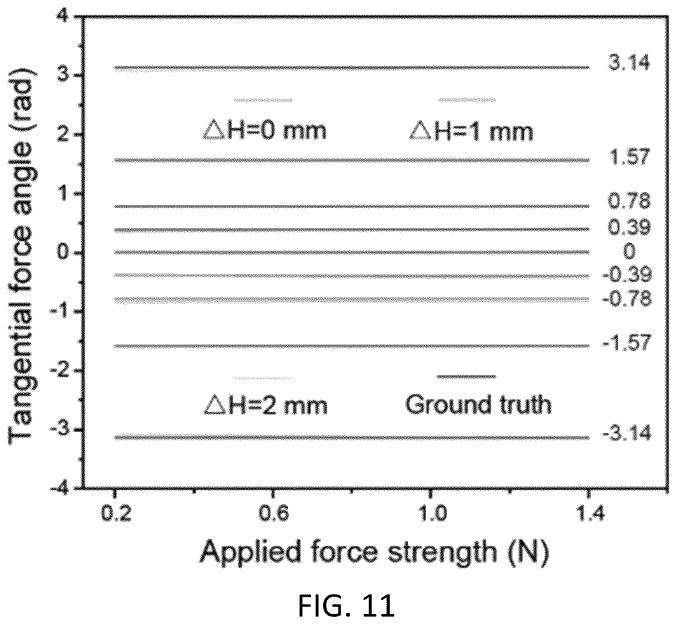

In FIG. 10, by correcting the signs of the tangential magnetic fields in the x and y directions, a completely linear angle relationship can be obtained. See values for ΔH=0 mm (1002), 1 mm (1004), and 2 mm (1006), whereby the single line shown in FIG. 10 has three lines superimposed upon each other corresponding to ΔH=0 mm (1002), 1 mm (1004), and 2 mm (1006). Thus, it can be concluded that the measured direction of the tangential force F is independent of the normal pressure (in the height direction)—and that measured direction of the tangential force is also independent of the magnitude of the tangential force (see FIG. 11). This also aligns with practical observations.

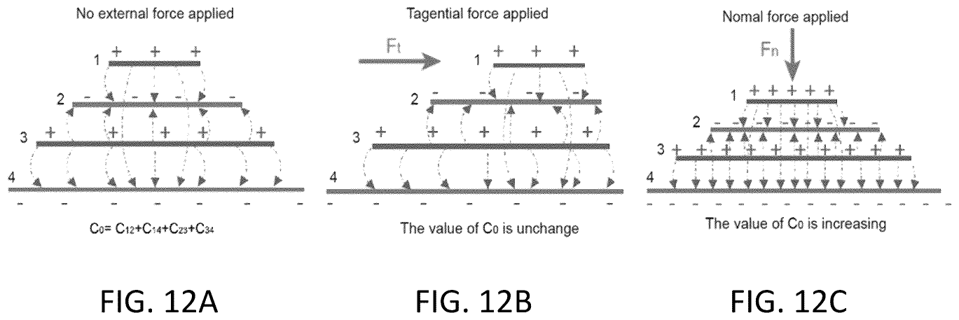

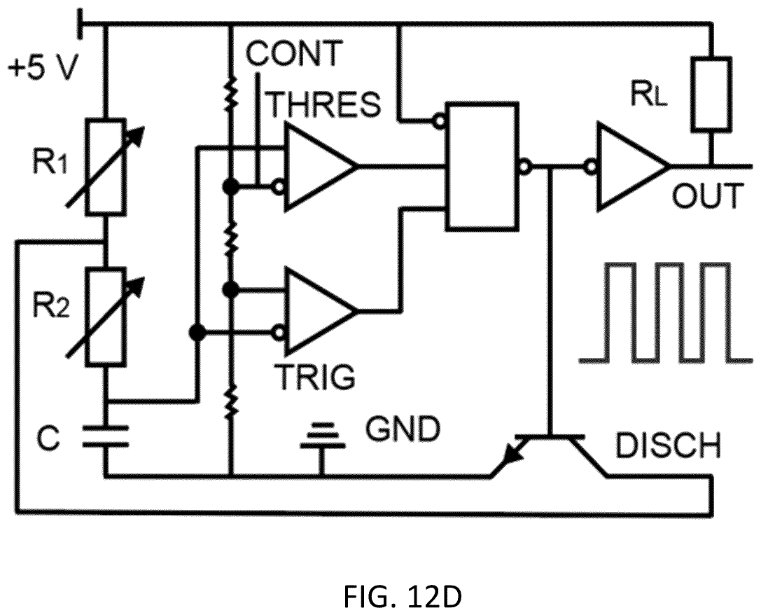

The measurement of normal force is based on changes in capacitance. To mitigate the influence of tangential forces, a floating-mountain multi-layer structure according to an exemplary embodiment of the present disclosure is used. FIG. 12A-12C depicts a schematic diagram showing an example of how tangential and normal forces affect an exemplary floating-mountain multi-layer structure according to an exemplary embodiment of the present disclosure. In particular, FIG. 12A illustrates a capacitor including two sets of positively and negatively charged electrodes with varying lengths, decreasing progressively from top to bottom, with no force applied.

When subjected to tangential forces, the electrodes undergo displacement within the horizontal plane, as shown in FIG. 12B. Due to the floating-mountain structural design, the effective area of the capacitor remains constant within the operational range. Therefore, the measurement of this capacitor in the normal direction can be independent of tangential forces.

When subjected to normal pressure as shown in FIG. 12C, the distance between the electrodes decreases, leading to an increase in capacitance. Consequently, by measuring the capacitance value, normal displacement and force can be correspondingly calculated.

FIG. 12D depicts a conversion circuit and how it can be connected to the capacitor as part of the sensor assembly in an embodiment. In FIG. 12D, C corresponds to a floating-mountain multi-layer capacitor; R1 and R2 are matching resistors; and the circuit output is a variable frequency square wave, where the frequency is determined by the size of the matching resistor and capacitor.

To facilitate capacitance measurement, such a conversion circuit may be employed to transform capacitance measurement into frequency measurement. The relationship between capacitance and output frequency may be as follows:

$$f = \frac{1}{ln ( 2 ) \cdot C \cdot ( {R}_{1} + 2 {R}_{2} )}$$

where f represents the output frequency, R₁ and R₂ denotes the resistance in the circuit, and C signifies the capacitance. This method enables accurate measurement of capacitance values and, consequently, normal forces while effectively decoupling them from tangential forces.

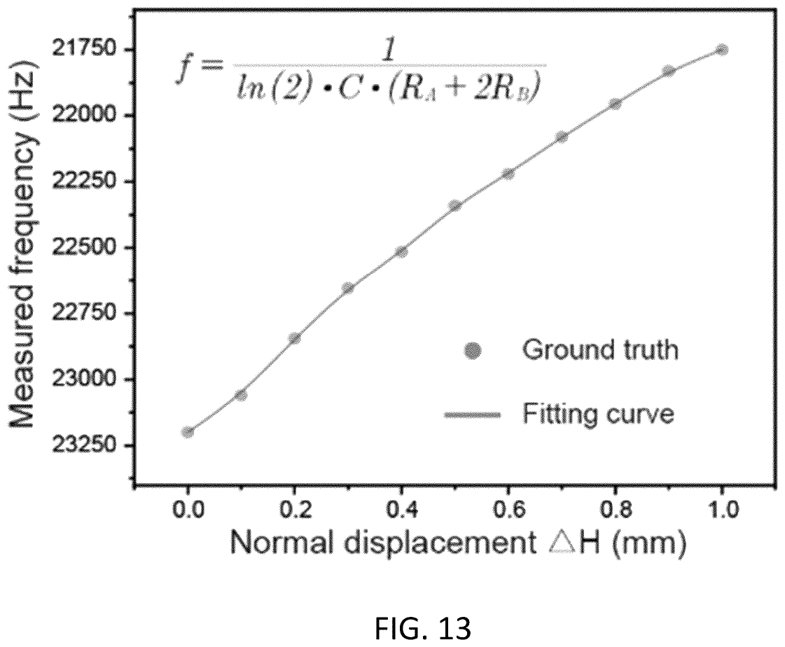

FIGS. 13-21 depict plots showing qualities and results of quantitative testing of an exemplary implementation of the present disclosure.

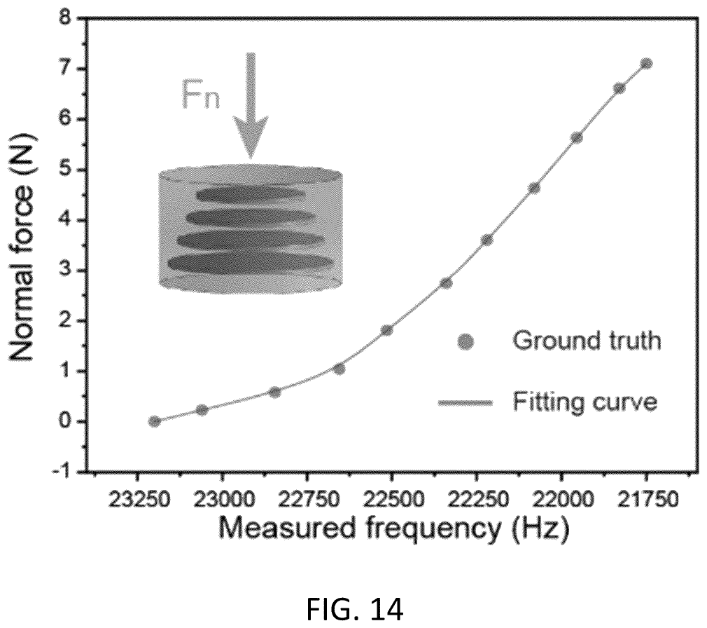

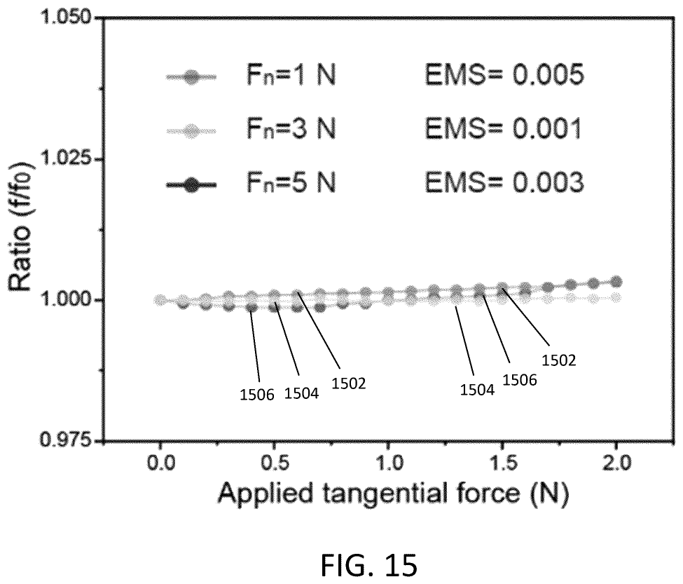

FIGS. 13 and 14 depict testing characterizing an exemplary configuration, establishing the relationship between normal displacement and output frequency (FIG. 13), as well as the relationship between normal force and output frequency (FIG. 14). Furthermore, testing has validated the independence of the floating-mountain multi-layered capacitor from tangential forces. FIG. 15 depicts results when a constant normal force is maintained while gradually increasing the tangential force from 0 to 2 Newtons, wherein the measured normal force remains stable. See values for Fn=1 N and EMS=0.005 (1502), Fn=3 N and EMS=0.001 (1504), and Fn=5 N and EMS=0.003 (1506). This demonstrates the independence and decoupling of normal force from tangential force, confirming the effectiveness of the design in isolating these two force components.

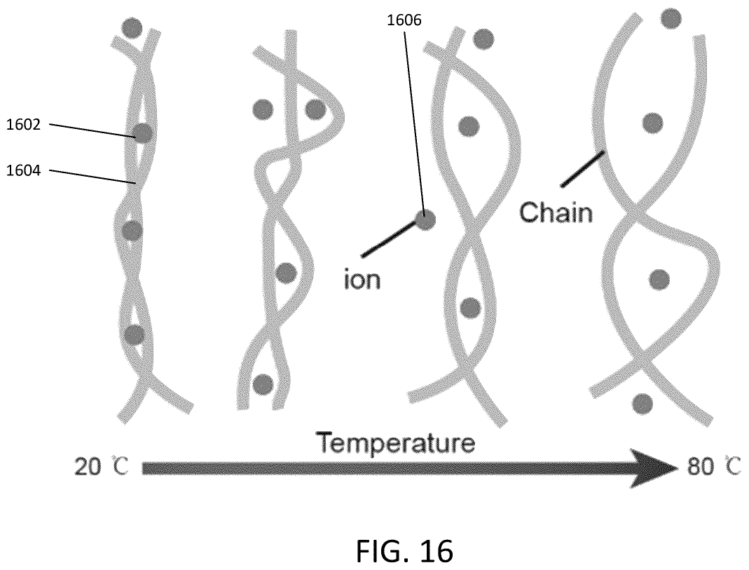

For temperature measurement, the temperature-sensitive properties of ion gels are utilized. Typically, ion gels contain two types of ions: non-free ions 1602 (which are bound and immobilized within polymer chains 1604) and free ions 1606 (which are unbound). When voltage is applied across the ends of the gel, the free ions 1606 move in response to the electric field, generating an electrical current. The greater the number of free ions 1606, the lower the resistance exhibited by the gel to the external circuit. As temperature increases, the distance between polymer chains 1604 within the gel increases, leading to the conversion of more non-free ions 1602 into free ions 1606. Ultimately, this results in the temperature-sensitive property of the gel, where its resistance decreases with increasing temperature. FIG. 16 depicts this relationship.

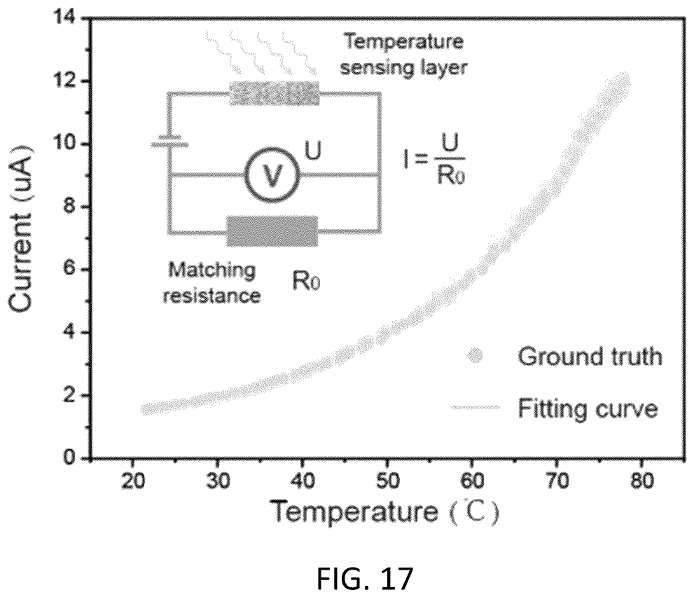

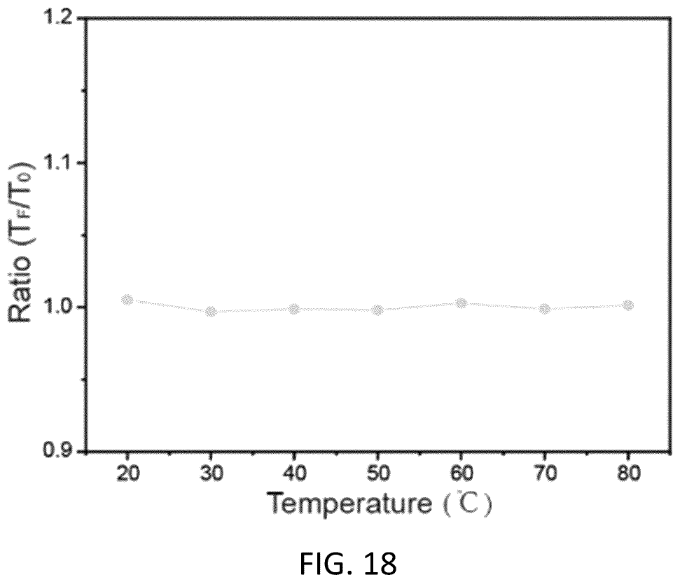

FIG. 17 shows the results, using an equivalent voltage divider circuit, of investigating the relationship between temperature and the current within the gel. In contrast to traditional temperature-sensitive materials, the apparent resistance of ion gel is solely related to the quantity of free ions within it and remains insensitive to external pressure or deformation. This property is advantageous for decoupled measurements of temperature and force, as confirmed in comparative experiments. FIG. 18 depicts an experimental comparison of temperature measurements with and without a load (10N). As the environmental temperature increases from 20 degrees to 80 degrees, the ratio of temperatures measured under the two conditions consistently remain between 0.99 and 1.01.

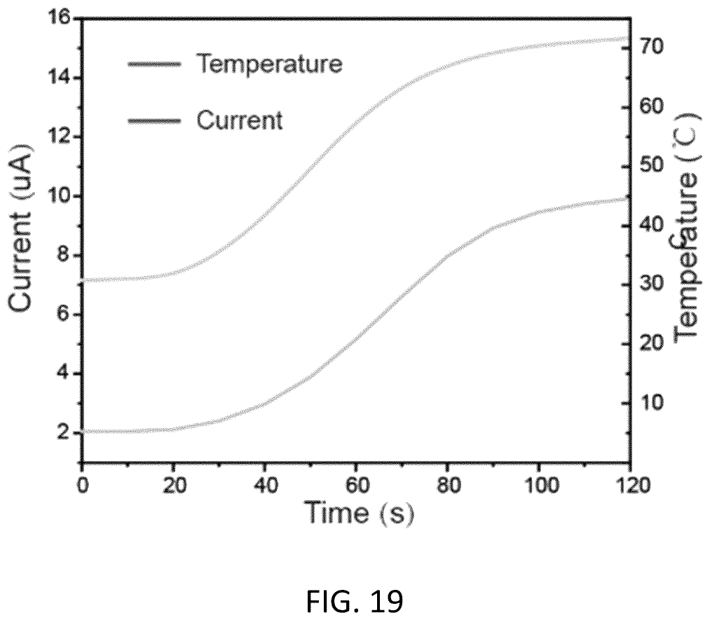

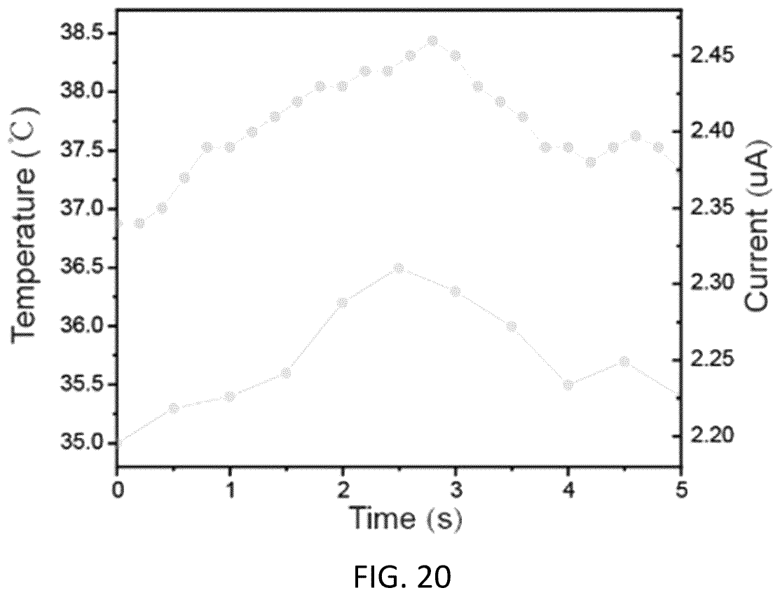

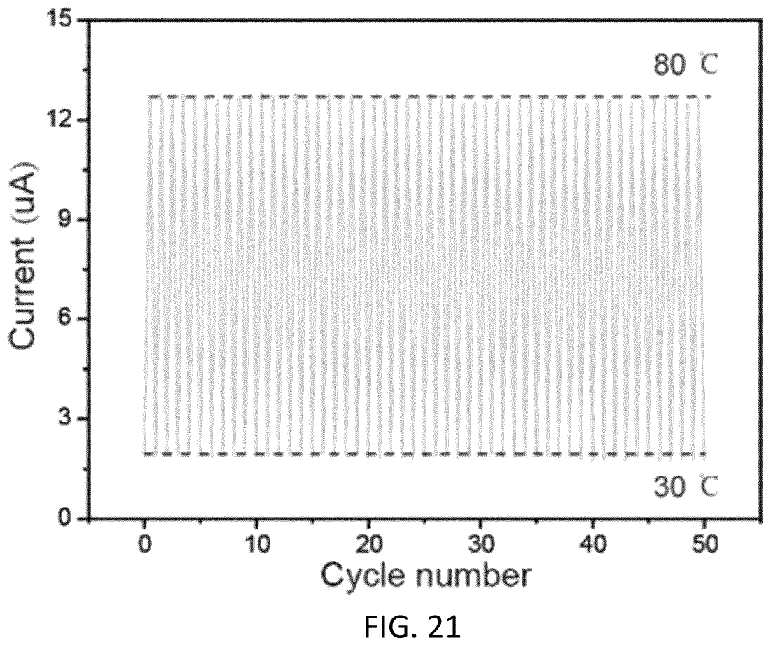

Furthermore, FIGS. 19 and 20 depict changes in current within the gel during slow and rapid temperature variations, respectively. They are in both cases nearly identical. However, due to the time delay in temperature conduction, the current changes lagged by 20-30 milliseconds. FIG. 21 demonstrates the repeatability of temperature sensing. After 50 cycles, the current change range within the ion gel showed almost no decay.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A sensor assembly, comprising:
a temperature sensing layer configured to detect temperature of an object contacting the sensor assembly;
at least one tangential force sensing layer configured to detect a tangential force applied by the object to the sensor assembly; and
a floating-mountain multi-layer capacitor configured to detect a normal force applied by the object to the sensor assembly.

2. The sensor assembly according to claim 1, wherein the temperature sensing layer is disposed above the at least one tangential force sensing layer and the floating mountain multi-layer capacitor, and wherein the temperature sensing layer provides a contact surface for the object or is closer to the contact surface for the object than the at least one tangential force sensing layer and the floating mountain multi-layer capacitor.

3. The sensor assembly according to claim 1, wherein the temperature sensing layer, the at least one tangential force sensing layer, and the floating-mountain multi-layer capacitor are connected to a controller or a processor.

4. The sensor assembly according to claim 3, wherein the controller or the processor is configured to independently determine the temperature of the object, the tangential force applied by the object, and the normal force applied by the object based on respective measurements from the temperature sensing layer, the tangential force sensing layer, and the floating-mountain multi-layer capacitor.

5. The sensor assembly according to claim 1, wherein the temperature sensing layer comprises a thermosensitive ion gel disposed within an encapsulation material.

6. The sensor assembly according to claim 1, wherein the at least one tangential force sensing layer comprises a Halbach magnetic film and a Hall sensor.

7. The sensor assembly according to claim 6, wherein the Hall sensor is disposed on a printed circuit board.

8. The sensor assembly according to claim 7, wherein the floating-mountain multi-layer capacitor is disposed between the Halbach magnetic film and the printed circuit board.

9. The sensor assembly according to claim 6, wherein the Halbach magnetic film comprises an inner portion having a first magnetization and a coaxial outer portion disposed around the inner portion and having a second magnetization opposite that of the inner portion.

10. The sensor assembly according to claim 1, wherein detecting the tangential force includes detecting a direction of the tangential force and a magnitude of the tangential force.

11. The sensor assembly according to claim 1, wherein the floating-mountain multi-layer capacitor comprises two positive electrodes and two negative electrodes.

12. The sensor assembly according to claim 11, wherein the two positive electrodes and the two negative electrodes are arranged within the floating-mountain multi-layer capacitor such that a first positive electrode is disposed above a first negative electrode, the first negative electrode is disposed above a second positive electrode, and the second positive electrode is disposed above a second negative electrode.

13. The sensor assembly according to claim 12, wherein the first positive electrode has a smaller width than the first negative electrode, the first negative electrode has a smaller width than the second positive electrode, and the second positive electrode has a smaller width than the second negative electrode.

14. The sensor assembly according to claim 12, wherein the first positive electrode is configured to move in a direction corresponding to the applied tangential force without interfering with the detection of the applied normal force.

15. The sensor assembly according to claim 1, wherein the floating-mountain multi-layer capacitor comprises electrodes, and wherein the floating-mountain multi-layer capacitor is configured such that a distance between the electrodes is decreased in a direction corresponding to the applied normal force based on application of the normal force.

16. The sensor assembly according to claim 1, wherein the floating-mountain multi-layer capacitor comprises electrodes embedded in an elastic material.

17. A floating-mountain multi-layer capacitor, comprising:
a plurality of electrodes; and
an elastic material encapsulating the plurality of electrodes;
wherein the plurality of electrodes and the elastic material are configured such that, based on a normal force being applied to the floating-mountain multi-layer capacitor, a distance between electrodes of the plurality of electrodes is decreased in a direction corresponding to the applied normal force.

18. The floating-mountain multi-layer capacitor according to claim 17, wherein the plurality of electrodes comprise two positive electrodes and the two negative electrodes arranged within the floating-mountain multi-layer capacitor such that a first positive electrode is disposed above a first negative electrode, the first negative electrode is disposed above a second positive electrode, and the second positive electrode is disposed above a second negative electrode.

19. The floating-mountain multi-layer capacitor according to claim 18, wherein the first positive electrode has a smaller width than the first negative electrode, the first negative electrode has a smaller width than the second positive electrode, and the second positive electrode has a smaller width than the second negative electrode.

20. An apparatus for sensing tangential force, the apparatus comprising:
a first layer comprising a Halbach magnetic film; and
a second layer comprising a Hall sensor disposed on a printed circuit board;
wherein the Hall sensor is configured to detect a voltage corresponding to displacement of the magnetic field based on an applied tangential force.

21. The apparatus according to claim 20, wherein the Halbach magnetic film comprises an inner portion having a first magnetization and a coaxial outer portion disposed around the inner portion and having a second magnetization opposite that of the inner portion.
